(19) United States
(12) Patent Application Publication
(10) Pub. No.: US 2022/0412776 A1
(43) Pub. Date: Dec. 29, 2022

(54) ELECTROSTATIC CAPACITANCE DETECTION CIRCUIT AND ELECTRONIC DEVICE

(71) Applicant: ROHM Co., LTD., Kyoto (JP)

(72) Inventor: Masao Nakajima, Kyoto (JP)

(21) Appl. No.: 17/808,129

(22) Filed: Jun. 22, 2022

(30) Foreign Application Priority Data
Jun. 25, 2021 (JP) 2021-105905

(51) Int. Cl. G01D 5/24; G06F 3/044

(52) U.S. Cl. CPC G01D 5/24; G06F 3/044

(57) ABSTRACT

Disclosed herein is an electrostatic capacitance detection circuit including a sense pin to which a sense electrode is to be connected, a ground pin to be grounded, a reference pin to be connected to a node where parasitic capacitance is to be formed between the node and the sense electrode, and a capacitance detection circuit connected to the sense pin, the ground pin, and the reference pin and configured to detect electrostatic capacitance formed by the sense electrode.

### CROSS REFERENCE TO RELATED APPLICATIONS

This application claims priority benefit of Japanese Patent Application No. JP 2021-105905 filed in the Japan Patent Office on Jun. 25, 2021. Each of the above-referenced applications is hereby incorporated herein by reference in its entirety.

### BACKGROUND

The present disclosure relates to an electrostatic capacitance detection circuit.

Electronic devices such as information terminals, office automation devices, and home appliances use electrostatic touch panels, electrostatic touchpads, or electrostatic switches (hereinafter collectively referred to as electrostatic sensors) as user interfaces. An electrostatic sensor includes a sensor electrode. Electrostatic capacitance is formed around the sensor electrode, and when a user's finger touches (or comes close to) the sensor electrode, the electrostatic capacitance changes. An electrostatic switch detects this small change in capacitance, thereby determining whether or not an input is made.

One example of the related art is Japanese Patent Laid-open No. 2020-166656.

### SUMMARY

As a result of examining electronic devices including electrostatic sensors, the present inventor has come to recognize the following issue.

FIG. 1 is a diagram schematically illustrating an electronic device including an electrostatic sensor. An electronic device 10 includes a sensor electrode 12 and a controller integrated circuit (IC) 14. A ground pin GND of the controller IC 14 is connected to a ground potential 16 such as a metal chassis of the electronic device 10 or a ground plane of a printed circuit board. A power supply voltage V_{DD} is supplied from a power supply circuit 20 to a power supply pin AVDD of the controller IC 14. Further, the sensor electrode 12 is connected to a sensing pin SNS of the controller IC 14. Electrostatic capacitance Cs formed around the sensor electrode 12 is the combined capacitance of electrostatic capacitance Cf formed between the sensor electrode 12 and a user's finger 2 and parasitic capacitance Cp formed between the sensor electrode 12 and a metal 18 located in the vicinity of the sensor electrode 12.

The controller IC 14 includes an electrostatic capacitance detection circuit that detects the electrostatic capacitance Cs formed by the sensor electrode 12. The electrostatic capacitance detection circuit detects the electrostatic capacitance Cs on the basis of the voltage of the GND pin. The electrostatic capacitance Cs can be accurately measured when the potential of the GND pin and the potential of the metal 18 are equal to the ground potential 16. However, parasitic impedance Z₁ such as parasitic resistance or parasitic inductance may exist between the metal 18 and the ground potential 16. Similarly, parasitic impedance Z₂ may exist between the GND pin and the ground potential 16. Therefore, when noise is generated at the ground potential 16 or other nodes, the potential difference between the GND pin and the ground potential 16 fluctuates with time. In this case, the component of the parasitic capacitance Cp included in the electrostatic capacitance Cs is detected under the influence of noise. This results in a decrease in the accuracy of detecting the electrostatic capacitance Cs. It is noted that the issue described herein is independently recognized by the present inventor and should not be considered as common recognition among those skilled in the art.

In view of the circumstances described above, it is desirable to provide an electrostatic capacitance detection circuit with improved detection accuracy.

An embodiment of the present disclosure relates to an electrostatic capacitance detection circuit. The electrostatic capacitance detection circuit includes a sense pin to which a sense electrode is to be connected, a ground pin to be grounded, a reference pin to be connected to a node where parasitic capacitance is to be formed between the node and the sense electrode, and a capacitance detection circuit connected to the sense pin, the ground pin, and the reference pin and configured to detect electrostatic capacitance formed by the sense electrode.

Another embodiment of the present disclosure also relates to an electrostatic capacitance detection circuit. The electrostatic capacitance detection circuit includes a sense pin, a ground pin, a reference pin, a first capacitor, a power supply line, a ground line connected to the ground pin, a first switch connected between a second end of the first capacitor and the sense pin, a second switch connected between the power supply line and the sense pin, a third switch connected between the reference pin and the ground line, a fourth switch connected in parallel to the first capacitor, a fifth switch connected between a first end of the first capacitor and the reference pin, a sixth switch connected between the first end of the first capacitor and the ground line, and a seventh switch connected between the reference pin and the ground line.

Yet another embodiment of the present disclosure also relates to an electrostatic capacitance detection circuit. The electrostatic capacitance detection circuit includes a sense pin, a ground pin, a reference pin, a first capacitor, a second capacitor, a power supply line, a ground line connected to the ground pin, a first switch connected between a second end of the first capacitor and the sense pin, a second switch connected between a second end of the second capacitor and the sense pin, a third switch connected between the reference pin and the ground line, a fourth switch connected in parallel to the first capacitor, a fifth switch connected between a first end of the first capacitor and the reference pin, a sixth switch connected between the first end of the first capacitor and the ground line, a seventh switch connected between the reference pin and the ground line, an eighth switch connected between the power supply line and the second end of the second capacitor, and a ninth switch connected in parallel to the second capacitor.

Any combination of the above-described constituent components as well as constituent components or expressions of the present disclosure obtained by exchanging the constituent components or the expressions among methods, devices, and systems are also effective as embodiments of the present disclosure.

According to an embodiment of the present disclosure, detection accuracy can be improved.

### BRIEF DESCRIPTION OF THE DRAWINGS

FIG. 1 is a diagram schematically illustrating an electronic device including an electrostatic sensor;

FIG. 2 is a circuit diagram of an electronic device including an electrostatic capacitance detection circuit according to an embodiment;

FIG. 3 is an exemplary sectional view of the electronic device;

FIG. 4 is a circuit diagram of an electrostatic capacitance detection circuit according to a first working example;

FIG. 5 is a time chart for describing sensing performed by the electrostatic capacitance detection circuit illustrated in FIG. 4;

FIG. 6 is a circuit diagram of an electrostatic capacitance detection circuit according to a comparative technique;

FIG. 7 illustrates voltage fluctuations in the electrostatic capacitance detection circuit illustrated in FIG. 6;

FIG. 8 illustrates voltage fluctuations in the electrostatic capacitance detection circuit illustrated in FIG. 4;

FIG. 9 is a circuit diagram of an electrostatic capacitance detection circuit according to a second working example; and

FIG. 10 is a time chart for describing sensing performed by the electrostatic capacitance detection circuit illustrated in FIG. 9.

### DETAILED DESCRIPTION OF THE PREFERRED EMBODIMENTS

### Overview of Embodiments

An overview of some exemplary embodiments of the present disclosure will be described. This overview is intended to simplify and describe some concepts of one or more embodiments for the purpose of basic understanding of the embodiments to be described in detail later and is not intended to limit the scope of the disclosure. This overview is not a comprehensive overview of all conceivable embodiments and is not intended to identify key elements of all the embodiments or delineate the scope of part or all of the aspects. For the sake of convenience, “one embodiment” may refer to one or more embodiments (working examples and modifications) disclosed in the present specification.

An electrostatic capacitance detection circuit according to one embodiment includes a sense pin to which a sense electrode is to be connected, a ground pin to be grounded, a reference pin to be connected to a node where parasitic capacitance is to be formed between the node and the sense electrode, and a capacitance detection circuit connected to the sense pin, the ground pin, and the reference pin and configured to detect electrostatic capacitance formed by the sense electrode.

With this configuration, the electrostatic capacitance detection circuit includes the reference pin in addition to the ground pin that serves as a ground terminal. Accordingly, noise of a ground line of an electronic device in which the electrostatic capacitance detection circuit is mounted is actively taken into the electrostatic capacitance detection circuit, and signal components are separated from noise components in the capacitance detection circuit. Accordingly, the detection accuracy can be improved.

In one embodiment, the capacitance detection circuit may include a first capacitor and may be configured to, (i) in a state in which the reference pin and the ground pin are electrically connected to each other, apply a voltage to the sense pin, and (ii) in a state in which the reference pin and the ground pin are electrically disconnected from each other, connect the first capacitor between the sense pin and the reference pin.

In one embodiment, the capacitance detection circuit may include a power supply line, a ground line connected to the ground pin, a first switch connected between one end of the first capacitor and the sense pin, a second switch connected between the power supply line and the sense pin, a third switch connected between the reference pin and the ground line, a fourth switch connected in parallel to the first capacitor, a fifth switch connected between another end of the first capacitor and the reference pin, a sixth switch connected between the other end of the first capacitor and the ground line, and a seventh switch connected between the reference pin and the ground line.

In one embodiment, the capacitance detection circuit may include a first capacitor and a second capacitor and may be configured to, (i) in a state in which one end of the second capacitor is connected to the ground pin, apply a voltage to another end of the second capacitor, (ii) in a state in which the reference pin and the ground pin are electrically connected to each other and the one end of the second capacitor is connected to the ground pin, connect the other end of the second capacitor to the sense pin, and (iii) in a state in which the reference pin and the ground pin are electrically disconnected from each other, connect the first capacitor between the sense pin and the reference pin.

In one embodiment, the capacitance detection circuit may include a power supply line, a ground line connected to the ground pin, a first switch connected between one end of the first capacitor and the sense pin, a second switch connected between one end of the second capacitor and the sense pin, a third switch connected between the reference pin and the ground line, a fourth switch connected in parallel to the first capacitor, a fifth switch connected between another end of the first capacitor and the reference pin, a sixth switch connected between the other end of the first capacitor and the ground line, a seventh switch connected between the reference pin and the ground line, an eighth switch connected between the power supply line and the one end of the second capacitor, and a ninth switch connected in parallel to the second capacitor.

An electrostatic capacitance detection circuit according to one embodiment includes a sense pin, a ground pin, a reference pin, a first capacitor, a power supply line, a ground line connected to the ground pin, a first switch connected between one end of the first capacitor and the sense pin, a second switch connected between the power supply line and the sense pin, a third switch connected between the reference pin and the ground line, a fourth switch connected in parallel to the first capacitor, a fifth switch connected between another end of the first capacitor and the reference pin, a sixth switch connected between the other end of the first capacitor and the ground line, and a seventh switch connected between the reference pin and the ground line.

An electrostatic capacitance detection circuit according to one embodiment includes a sense pin, a ground pin, a reference pin, a first capacitor, a second capacitor, a power supply line, a ground line connected to the ground pin, a first switch connected between one end of the first capacitor and the sense pin, a second switch connected between one end of the second capacitor and the sense pin, a third switch connected between the reference pin and the ground line, a fourth switch connected in parallel to the first capacitor, a fifth switch connected between another end of the first capacitor and the reference pin, a sixth switch connected between the other end of the first capacitor and the ground line, a seventh switch connected between the reference pin and the ground line, an eighth switch connected between the power supply line and the one end of the second capacitor, and a ninth switch connected in parallel to the second capacitor.

In one embodiment, the electrostatic capacitance detection circuit may be integrated on a single semiconductor substrate. The term “integrated” herein may include a case where all the constituent components of a circuit are formed on a semiconductor substrate or a case where main constituent components of the circuit are integrated thereon, and some resistors, capacitors, and other components may be disposed outside the semiconductor substrate in order to adjust circuit constants. By integrating a circuit on a single chip, it is possible to reduce a circuit area and keep characteristics of circuit elements uniform.

### EMBODIMENTS

Hereinafter, preferred embodiments will be described with reference to the drawings. The same or equivalent constituent components, members, and processes illustrated in the drawings will be denoted by the same reference signs, and redundant description will be omitted as appropriate. The embodiments will be described for exemplary purposes only and are by no means intended to limit the present disclosure. All the features and combinations described in the embodiments are not necessarily essential to the disclosure.

In the present specification, “the state in which a member A is connected to a member B” includes not only the state in which the member A and the member B are physically directly connected to each other but also the state in which the member A and the member B are indirectly connected to each other via another member that has no substantial effect on the electrical connection between them or that does not impair a function or effect produced by the connection between them.

Similarly, “the state in which a member C is disposed between the member A and the member B” includes not only the state in which the member A and the member C or the member B and the member C are directly connected to each other but also the state in which the member A and the member C or the member B and the member C are indirectly connected to each other via another member that has no substantial effect on the electrical connection between them or that does not impair a function or effect produced by the connection between them.

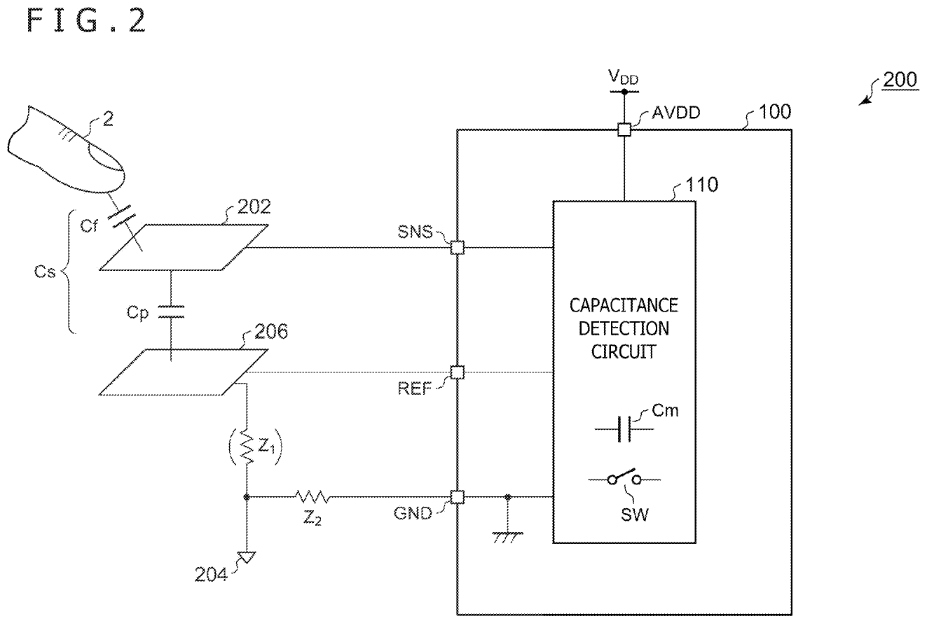

FIG. 2 is a circuit diagram of an electronic device 200 including an electrostatic capacitance detection circuit 100 according to an embodiment. The electronic device 200 includes a sense electrode 202, a ground potential 204, a reference node 206, and the electrostatic capacitance detection circuit 100. The ground potential 204 is a metal housing of the electronic device 200 or a ground plane of a printed circuit board.

The electrostatic capacitance detection circuit 100 constitutes an electrostatic sensor, together with the sense electrode 202. The type of electrostatic sensor is not particularly limited, and the electrostatic sensor may be an electrostatic touch panel, an electrostatic touchpad, an electrostatic switch, or other sensors.

The sense electrode 202 forms electrostatic capacitance Cs between the sense electrode 202 and its surroundings. The electrostatic capacitance Cs includes electrostatic capacitance Cf formed between the sense electrode 202 and a user's finger 2 (or a stylus) and parasitic capacitance Cp formed between the sense electrode 202 and the reference node 206. The reference node 206 is wiring, a metal plate, or a metal chassis, for example, on the printed circuit board of the electronic device 200.

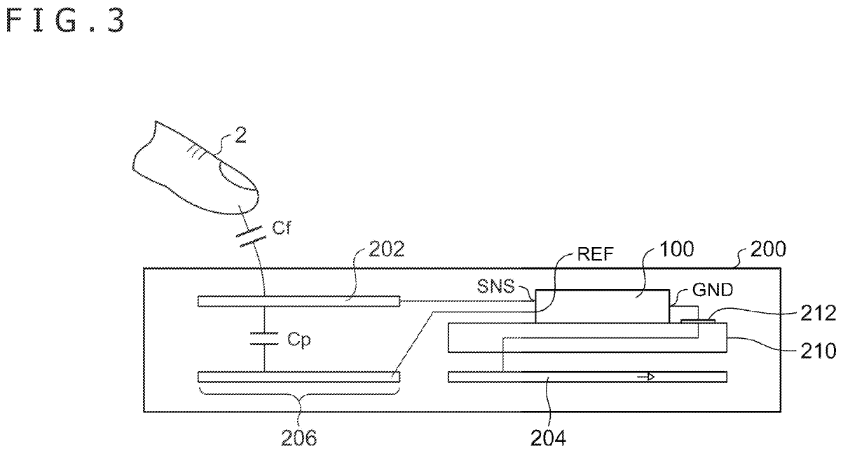

A capacitance detection circuit 110 is mounted on a printed circuit board 210 (see FIG. 3), and a ground pin GND of the electrostatic capacitance detection circuit 100 is connected to a ground pattern of the printed circuit board 210. The ground pattern is electrically connected to the ground potential 204. A sense pin SNS of the electrostatic capacitance detection circuit 100 is connected to the sense electrode 202. A reference pin REF of the electrostatic capacitance detection circuit 100 is connected to the reference node 206.

The electrostatic capacitance detection circuit 100 monitors the electrostatic capacitance Cs formed by the sense electrode 202 and detects a touch or proximity of the finger 2 to the sense electrode 202 according to a change in the electrostatic capacitance Cs.

The electrostatic capacitance detection circuit 100 includes the sense pin SNS, the ground pin GND, the reference pin REF, and the capacitance detection circuit 110 and is a functional integrated circuit (IC) integrated on a single semiconductor substrate.

The sense pin SNS is connected to the sense electrode 202. The ground pin GND is connected to the ground potential 204. That is, the ground pin GND is grounded. The reference pin REF is connected to the reference node 206 where the parasitic capacitance Cp can be formed between the reference node 206 and the sense electrode 202.

The capacitance detection circuit 110 is connected to the sense pin SNS, the ground pin GND, and the reference pin REF and is configured to detect the electrostatic capacitance Cs formed by the sense electrode 202.

FIG. 3 is an exemplary sectional view of the electronic device 200. The electronic device 200 includes the sense electrode 202, a metal chassis that serves as the ground potential 204, the printed circuit board 210, and the electrostatic capacitance detection circuit 100. In this example, the reference node 206 is a piece of metal or electrode insulated from the metal chassis that serves as the ground potential 204, and the parasitic capacitance Cp is formed between the reference node 206 and the sense electrode 202. The reference node 206 and the ground potential 204 may be electrically connected to each other.

Referring back to FIG. 2, an impedance component Z₂ such as parasitic resistance or parasitic inductance may exist between the ground pin GND of the electrostatic capacitance detection circuit 100 and the ground potential 204. Further, the reference node 206 and the ground potential 204 may be electrically insulated from each other, and an impedance component Z₁ such as parasitic resistance or parasitic inductance may exist between the reference node 206 and the ground potential 204. The magnitude relation between Z₁ and Z₂ is not limited. If the reference node 206 can be considered insulated from the ground potential 204 as illustrated in FIG. 3, Z₁ is substantially infinite. Z₂ is the impedance of wiring and via holes in the printed circuit board 210.

A specific configuration of the capacitance detection circuit 110 is not particularly limited. For example, the capacitance detection circuit 110 includes an internal capacitor Cm and a plurality of switches (collectively referred to as a switch SW). The capacitance detection circuit 110 detects the electrostatic capacitance Cs by performing the following steps.

Step 1: A voltage is applied to the sense electrode 202 via the sense pin SNS to charge the electrostatic capacitance Cs.

Step 2: Electric charge in the electrostatic capacitance Cs is transferred to the internal capacitor Cm.

Step 3: A voltage generated in the internal capacitor Cm is detected.

At step 1, the electrostatic capacitance Cs is charged based on the potential of the ground pin GND in the state in which the reference pin REF and the ground pin GND are short-circuited using the switch SW.

At step 2, the electric charge is transferred in the state in which the reference pin REF and the ground pin GND are disconnected from each other. Specifically, in the state in which the reference pin REF and the ground pin GND are electrically disconnected from each other, the internal capacitor Cm is connected between the sense pin SNS and the reference pin REF.

The configurations of the electrostatic capacitance detection circuit 100 and the electronic device 200 are as described above. Next, the operation of the electrostatic capacitance detection circuit 100 will be described.

The electrostatic capacitance detection circuit 100 includes the reference pin REF in addition to the ground pin GND. With this configuration, noise of the ground potential 204 of the electronic device 200 in which the electrostatic capacitance detection circuit 100 is mounted is actively taken into the electrostatic capacitance detection circuit 100, and signal components are separated from noise components in the capacitance detection circuit 110. Accordingly, the detection accuracy can be improved.

The present disclosure extends to various devices and methods each understood as the block diagram or circuit diagram of FIG. 2 or derived from the above description, and is not limited to a specific configuration. Hereinafter, more specific configuration examples and working examples will be described not to narrow the scope of the present disclosure but to help understand the essence and operation of the present disclosure and to clarify them.

### First Working Example

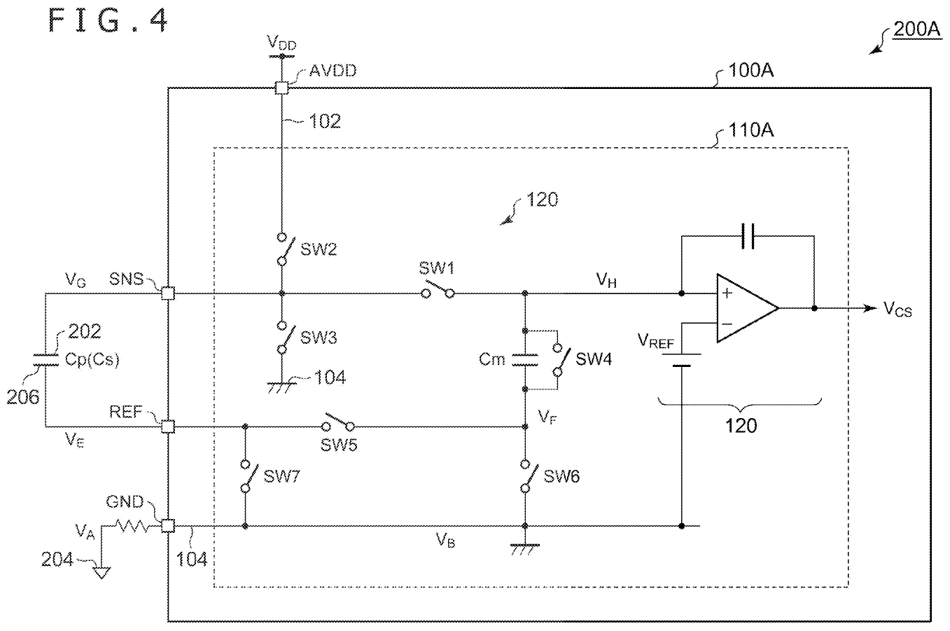

FIG. 4 is a circuit diagram of an electrostatic capacitance detection circuit 100A according to a first working example. The electrostatic capacitance detection circuit 100A includes a power supply line 102, a ground line 104, and a capacitance detection circuit 110A. A power supply voltage V_{DD} is supplied to the power supply line 102, which is connected to a power supply pin AVDD. The ground line 104 is connected to a ground pin GND.

The capacitance detection circuit 110A includes a first capacitor Cm, a switch group including a plurality of switches SW1 to SW7, and an amplifier 120.

The first switch SW1 is connected between one end of the first capacitor Cm and a sense pin SNS. The second switch SW2 is connected between the power supply line 102 and the sense pin SNS. The third switch SW3 is connected between a reference pin REF and the ground line 104. The fourth switch SW4 is connected in parallel to the first capacitor Cm. The fifth switch SW5 is connected between the other end of the first capacitor Cm and the reference pin REF. The sixth switch SW6 is connected between the other end of the first capacitor Cm and the ground line 104. The seventh switch SW7 is connected between the reference pin REF and the ground line 104.

The amplifier 120 amplifies the voltage of the first capacitor Cm and generates a detection signal Vcs.

The configuration of the electrostatic capacitance detection circuit 100A is as described above. Next, the operation of the electrostatic capacitance detection circuit 100A will be described.

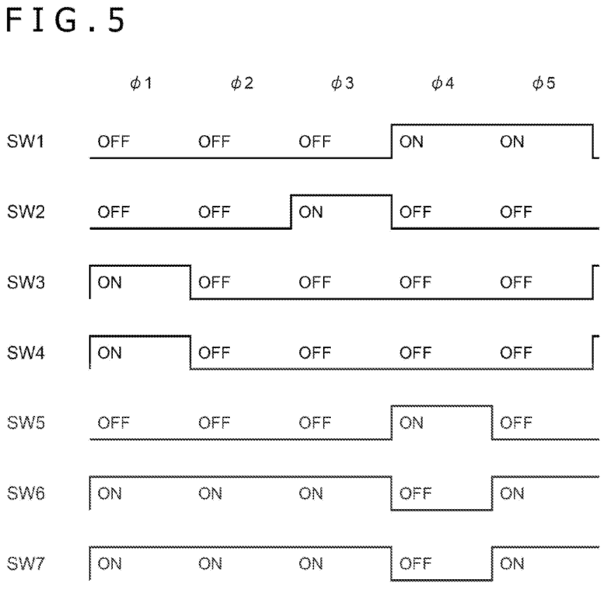

FIG. 5 is a time chart for describing the sensing performed by the electrostatic capacitance detection circuit 100A illustrated in FIG. 4. The electrostatic capacitance detection circuit 100A transitions from a first state φ1 to a fifth state φ5 in order.

The first state (l is an initialization phase in which the switches SW3, SW4, SW6, and SW7 are ON. Accordingly, electric charge in electrostatic capacitance Cs including parasitic capacitance Cp (that is, voltage across the electrostatic capacitance Cs including the parasitic capacitance Cp), and electric charge in the first capacitor Cm (voltage across the first capacitor Cm) are initialized.

In the second state φ2, the switches SW6 and SW7 are ON. The second state φ2 may be omitted.

The subsequent third state φ3 is a charging phase in which the switches SW2, SW6, and SW7 are ON. In the charging phase, a predetermined voltage (in this example, the power supply voltage V_{DD}) is applied to the electrostatic capacitance Cs to charge the electrostatic capacitance Cs. In the third state φ3, the switch SW2 is turned on, by which the power supply voltage V_{DD} is applied to the sense pin SNS. Further, since the switch SW7 is also ON, the reference pin REF and the ground pin GND are electrically connected to each other. In the third state φ3, the switch SW5 may also be ON.

The subsequent fourth state φ4 is an electric charge transferring phase in which the switches SW1 and SW5 are ON and the first capacitor Cm is connected in parallel to the electrostatic capacitance Cs. In the fourth state φ4, electric charge is transferred in the state in which the capacitor Cm and Cs float from the ground pin GND of the electrostatic capacitance detection circuit 100A.

The subsequent fifth state φ5 is an amplification phase in which the switches SW1, SW6, and SW7 are ON. Accordingly, one end of the electrostatic capacitance Cs and one end of the first capacitor Cm are connected to the ground pin GND via the ground line 104, while the other ends thereof are connected to an input node of the amplifier 120. At this time, the detection signal Vcs corresponding to the electrostatic capacitance Cs is generated at the output of the amplifier 120.

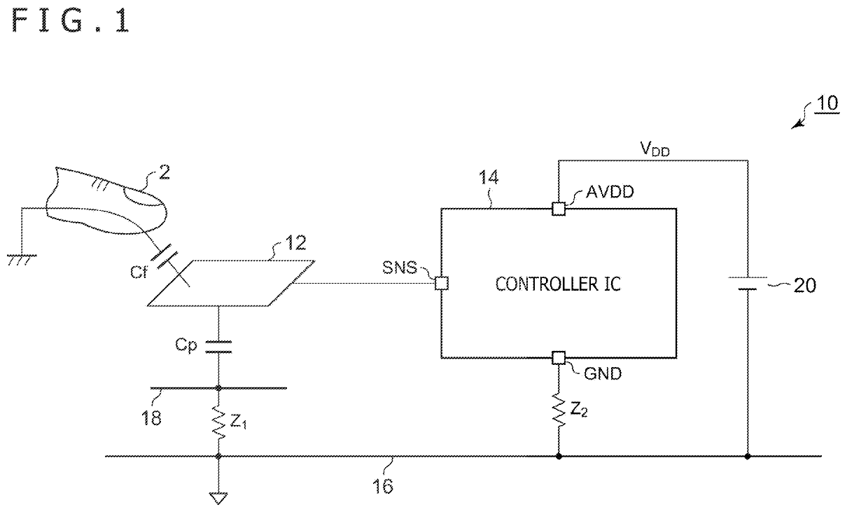

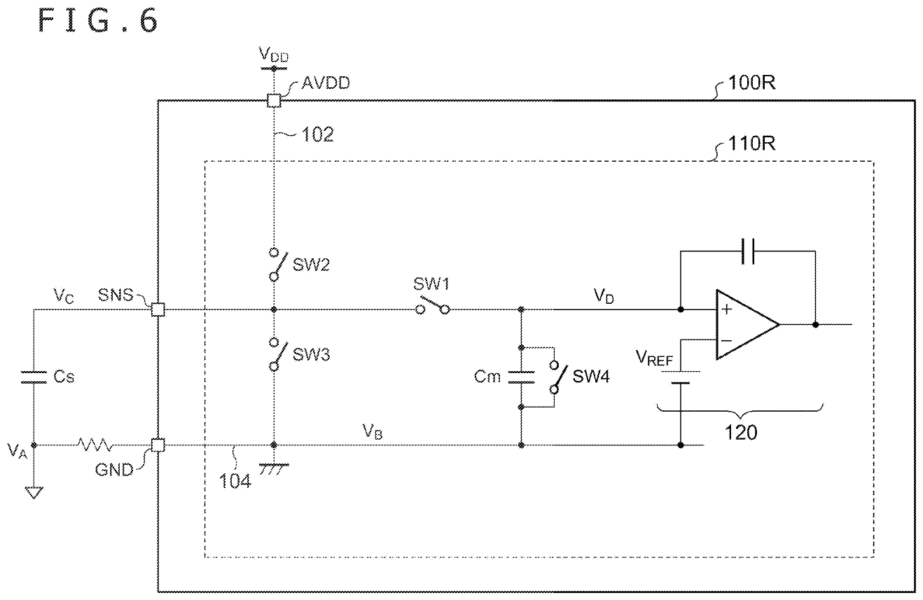

An advantage of the electrostatic capacitance detection circuit 100A according to the first working example becomes clear by comparing it with that of a comparative technique. FIG. 6 is a circuit diagram of an electrostatic capacitance detection circuit 100R according to the comparative technique. The electrostatic capacitance detection circuit 100R includes a ground pin GND but does not include a reference pin REF as illustrated in FIG. 1. Further, the electrostatic capacitance detection circuit 100R does not include switches SW5 to SW7.

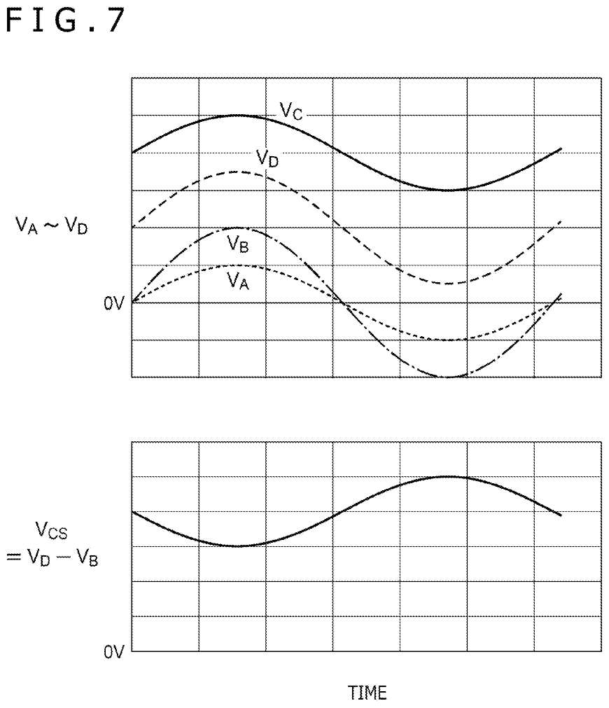

FIG. 7 illustrates voltage fluctuations in the electrostatic capacitance detection circuit 100R illustrated in FIG. 6. The upper part of FIG. 7 illustrates four voltages V_{A} to V_{D}. V_{A} represents the ground voltage of an electronic device. V_{B} represents the voltage of the ground pin GND of the electrostatic capacitance detection circuit 100R. V_{C} represents the voltage of a sense pin SNS in a charging phase. V_{D} represents the input voltage of an amplifier 120 after an electric charge transferring phase in which a switch SW1 is ON, that is, the voltage generated at a node on the high potential side of a capacitor Cm.

Assume that the ground voltage V_{A} of the electronic device includes alternate current (AC) noise. Since there is non-negligible impedance between the ground of the electronic device and the ground pin GND of the electrostatic capacitance detection circuit 100R, the voltage V_{B} of the ground pin GND of the electrostatic capacitance detection circuit 100R has an amplitude different from that of the voltage V_{A} of the outer ground.

The voltage V_{C}, that is, the charging voltage of the sense pin SNS in the charging phase in which a switch SW2 is ON is equal to the power supply voltage V_{DD}. Since the power supply voltage V_{DD} is generated based on the ground voltage V_{A} of the electronic device, the power supply voltage V_{DD} also changes following the ground voltage V_{A}. Electric charge Qs charged to electrostatic capacitance Cs in the charging phase is expressed by the following equation (1).

Qs=V_{C}×Cs (1)

From the law of conservation of electric charge, the following equation (2) holds.

Cs×V_{C}=Cs×V_{D}+Cm×(V_{D}−V_{B}) (2)

Solving this for V_{D} yields the following equation (3).

V_{D}=(Cs×V_{C}+Cm×V_{B})/(Cs+Cm) (3)

Since the amplifier 120 operates based on the ground voltage V_{B} of the IC, a detection signal Vcs is proportional to (V_{D}−V_{B}). That is, in the electrostatic capacitance detection circuit 100R illustrated in FIG. 6, the detection signal Vcs fluctuates with time. In other words, the detection signal Vcs varies depending on the timing of sensing (SW1 is ON).

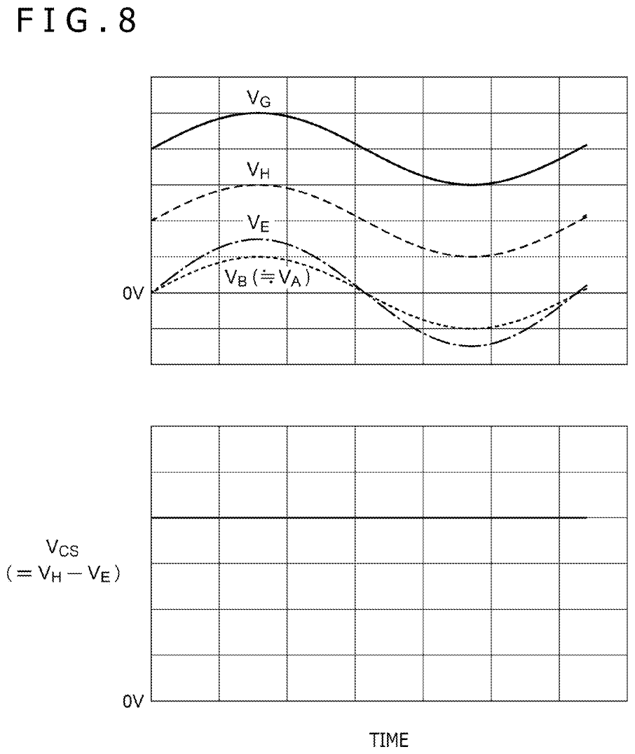

FIG. 8 illustrates voltage fluctuations in the electrostatic capacitance detection circuit 100A illustrated in FIG. 4. The upper part of FIG. 8 illustrates four voltages V_{B}, V_{E}, V_{G}, and V_{H}. V_{B} represents the potential of the ground pin GND, that is, the reference potential of the electrostatic capacitance detection circuit 100A. When AC noise is superimposed on the potential V_{A} of a ground potential 204 of an electronic device 200A, the potential of the ground pin GND is also influenced by the noise.

V_{E} represents the voltage of a reference node 206 (reference pin REF) in the state in which the reference node 206 and the ground pin GND are not connected to each other in the electrostatic capacitance detection circuit 100A. In the electrostatic capacitance detection circuit 100A, a voltage V_{E}′ when the reference node 206 (reference pin REF) and the ground pin GND are connected to each other is equal to V_{B} (V_{E}′=V_{B}).

V_{G} represents the voltage of the sense pin SNS in the charging phase. The voltage V_{G} of the sense pin SNS in the charging phase in which the switch SW2 is ON is equal to the power supply voltage V_{DD}. Since the power supply voltage V_{DD} is generated based on the ground voltage V_{A} of the electronic device, the power supply voltage V_{DD} also changes following the ground voltage V_{A}. Assuming that V_{A}=V_{B} for ease of understanding here, the voltage (charging voltage) across the electrostatic capacitance Cs in the charging phase is V_{G}−V_{B} (≈V_{DD}−V_{A}) and is a constant voltage.

V_{H} represents the input voltage of the amplifier 120 after the electric charge transferring phase, that is, the voltage generated at the node on the high potential side of the capacitor Cm.

Since the charging phase is performed based on the ground potential 204, the amount of electric charge Qchg stored in the electrostatic capacitance Cs is expressed by the following equation (4).

Qchg=Cs×(V_{G}−V_{B}) (4)

The electric charge is transferred in the state in which the electrostatic capacitance Cs and the first capacitor Cm are disconnected from the ground potential 204. From the law of conservation of electric charge, the following equation (5) holds.

Cs×(V_{G}−V_{B})=Cs×(V_{H}−V_{E})+Cm×(V_{H}−V_{F}) (5)

Here, since the fifth switch SW5 is ON in the electric charge transferring phase, V_{E}=V_{F} holds.

Cs×(V_{G}−V_{B})=Cs×(V_{H}−V_{E})+Cm×(V_{H}−V_{E}) (6)

Solving this for (V_{H}−V_{E}) yields the following equation (7).

(V_{H}−V_{E})=(V_{G}−V_{B})×Cs/(Cs+Cm) (7)

The detection signal Vcs is proportional to (V_{H}−V_{E}). In the equation (7), (V_{G}−V_{B}) is a time-independent constant. Accordingly, the detection signal Vcs is also time-independent.

In this way, according to the first working example, the influence of noise can be canceled, and sensing can be performed with high accuracy.

### Second Working Example

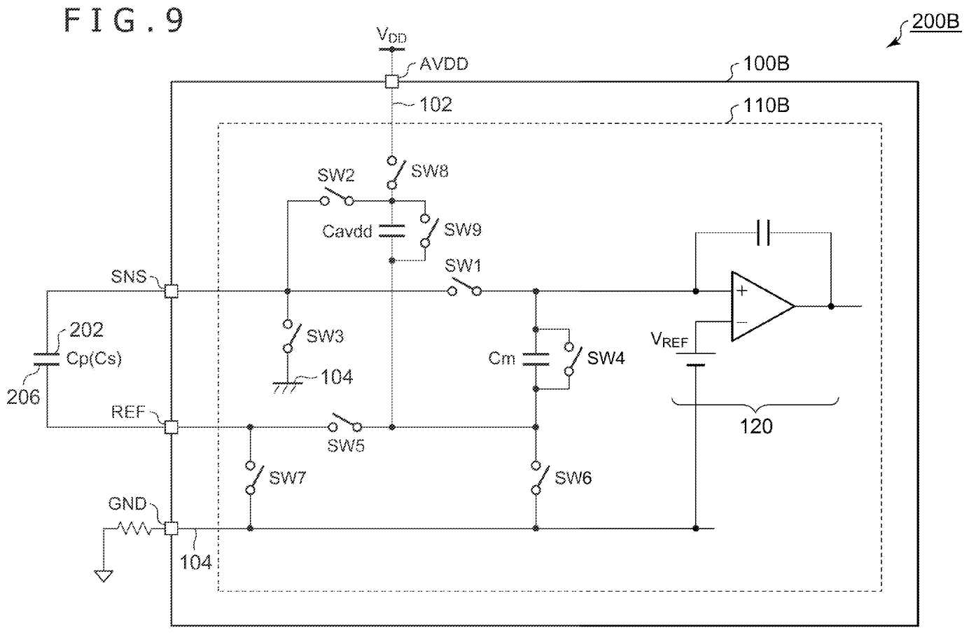

FIG. 9 is a circuit diagram of an electrostatic capacitance detection circuit 100B according to a second working example. The electrostatic capacitance detection circuit 100B includes a power supply line 102, a ground line 104, and a capacitance detection circuit 110B. A power supply voltage V_{DD} is supplied to the power supply line 102, which is connected to a power supply pin AVDD. The ground line 104 is connected to a ground pin GND.

The capacitance detection circuit 110B includes a first capacitor Cm, a second capacitor Cavdd, a switch group including a plurality of switches SW1 to SW9, and an amplifier 120.

The capacitance detection circuit 110B is configured to, (i) in the state in which one end of the second capacitor Cavdd is connected to the ground pin GND, apply a voltage V_{DD} to the other end of the second capacitor Cavdd, and subsequently, (ii) in the state in which a reference pin REF and the ground pin GND are electrically connected to each other and the one end of the second capacitor Cavdd is connected to the ground pin GND, connect the other end of the second capacitor Cavdd to a sense pin SNS. Accordingly, electrostatic capacitance Cs(Cp) is charged.

Subsequently, (iii) in the state in which the reference pin REF and the ground pin GND are electrically disconnected from each other, the first capacitor Cm is connected between the sense pin SNS and the reference pin REF. Accordingly, the electric charge in the electrostatic capacitance Cs is transferred to the first capacitor Cm.

The switch group is configured in such a manner that the states (i) to (iii) can be realized, and its specific configuration is not particularly limited. In the present working example, the nine switches SW1 to SW9 realize this function.

The first switch SW1 is connected between one end of the first capacitor Cm and the sense pin SNS. The second switch SW2 is connected between one end of the second capacitor Cavdd and the sense pin SNS. The third switch SW3 is connected between the reference pin REF and the ground line 104. The fourth switch SW4 is connected in parallel to the first capacitor Cm. The fifth switch SW5 is connected between the other end of the first capacitor Cm and the reference pin REF. The sixth switch SW6 is connected between the other end of the first capacitor Cm and the ground line 104. The seventh switch SW7 is connected between the reference pin REF and the ground line 104. The eighth switch SW8 is connected between the power supply line 102 and the one end of the second capacitor Cavdd. The ninth switch SW9 is connected in parallel to the second capacitor Cavdd.

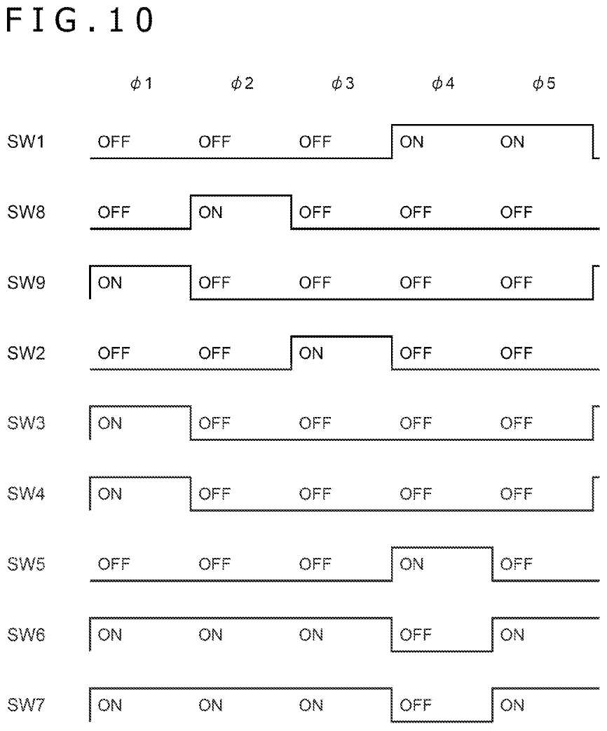

FIG. 10 is a time chart for describing sensing performed by the electrostatic capacitance detection circuit 100B illustrated in FIG. 9. The electrostatic capacitance detection circuit 100B transitions from a first state φ1 to a fifth state φ5 in order.

The first state φ1 is an initialization phase in which the switches SW9, SW3, SW4, SW6, and SW7 are ON. Accordingly, electric charge in the electrostatic capacitance Cs including parasitic capacitance Cp (that is, voltage across the electrostatic capacitance Cs including the parasitic capacitance Cp), electric charge in the first capacitor Cm (voltage across the first capacitor Cm), and electric charge in the second capacitor Cavdd (voltage across the second capacitor Cavdd) are initialized.

In the second state φ2, the switches SW8, SW6, and SW7 are ON. Accordingly, the second capacitor Cavdd is charged by the power supply voltage V_{DD}. This is also called a pre-charging phase.

The subsequent third state φ3 is a charging phase in which the switches SW2, SW6, and SW7 are ON. In the charging phase, the electrostatic capacitance Cs is charged by using the electric charge stored in the second capacitor Cavdd. In the third state φ3, the switch SW5 may also be ON.

The subsequent fourth state φ4 is an electric charge transferring phase in which the switches SW1 and SW5 are ON and the first capacitor Cm is connected in parallel to the electrostatic capacitance Cs. In the fourth state φ4, electric charge is transferred in the state in which the capacitor Cm and Cs float from the ground pin GND of the electrostatic capacitance detection circuit 100B.

The subsequent fifth state φ5 is an amplification phase in which the switches SW1, SW6, and SW7 are ON. Accordingly, one end of the electrostatic capacitance Cs and one end of the first capacitor Cm are connected to the ground pin GND via the ground line 104, while the other ends thereof are connected to an input node of the amplifier 120. At this time, a detection signal Vcs corresponding to the electrostatic capacitance Cs is generated at the output of the amplifier 120.

The configuration of the electrostatic capacitance detection circuit 100B is as described above. According to the electrostatic capacitance detection circuit 100B, the influence of noise can be canceled, and sensing can be performed with high accuracy, as with the electrostatic capacitance detection circuit 100A according to the first working example.

### Modifications

The embodiments described above are for exemplary purposes only, and it is to be understood by those skilled in the art that various modifications can be made to combinations of the constituent components and processes of the embodiments. The following describes such modifications.

### First Modification

The topology of the plurality of switches SW1 to SW7 of the capacitance detection circuit 110A according to the first working example is not limited to that of FIG. 4.

If the impedance of the switches is sufficiently low, one of the two switches SW6 and SW7 may be omitted.

Further, referring to FIG. 4, the third switch SW3 may be connected between the sense pin SNS and the reference pin REF.

Further, referring to FIG. 4, the fourth switch SW4 may be connected between one end on the high potential side of the first capacitor Cm and the ground line 104.

### Second Modification

The topology of the plurality of switches SW1 to SW9 of the capacitance detection circuit 110B according to the second working example is not limited to that of FIG. 9.

If the impedance of the switches is sufficiently low, one of the two switches SW6 and SW7 may be omitted.

Further, referring to FIG. 9, the third switch SW3 may be connected between the sense pin SNS and the reference pin REF.

Further, referring to FIG. 9, the fourth switch SW4 may be connected between one end on the high potential side of the first capacitor Cm and the ground line 104.

Further, referring to FIG. 9, the ninth switch SW9 may be connected between one end on the high potential side of the second capacitor Cavdd and the ground line 104.

The embodiments described above are for exemplary purposes only, and it is to be understood by those skilled in the art that various modifications can be made to combinations of the constituent components and processes of the embodiments and that such modifications also fall within the scope of the present disclosure.

What is claimed is:

1. An electrostatic capacitance detection circuit comprising:
a sense pin to which a sense electrode is to be connected;
a ground pin to be grounded;
a reference pin to be connected to a node where parasitic capacitance is to be formed between the node and the sense electrode; and
a capacitance detection circuit connected to the sense pin, the ground pin, and the reference pin and configured to detect electrostatic capacitance formed by the sense electrode.

2. The electrostatic capacitance detection circuit according to claim 1,
wherein the capacitance detection circuit includes a first capacitor and is configured to, (i) in a state in which the reference pin and the ground pin are electrically connected to each other, apply a voltage to the sense pin, and (ii) in a state in which the reference pin and the ground pin are electrically disconnected from each other, connect the first capacitor between the sense pin and the reference pin.

3. The electrostatic capacitance detection circuit according to claim 2,
wherein the capacitance detection circuit is switchable among
a state in which electric charge in the electrostatic capacitance and electric charge in the first capacitor are initialized to zero,
a state in which the reference pin and the ground pin are connected to each other and a voltage is applied to the sense pin,
a state in which the reference pin and the ground pin are electrically disconnected from each other and the first capacitor is connected between the sense pin and the reference pin, and
a state in which a first end on a low potential side of the first capacitor is connected to the ground pin and a voltage of the first capacitor is amplified.

4. The electrostatic capacitance detection circuit according to claim 2,
wherein the capacitance detection circuit includes
a power supply line,
a ground line connected to the ground pin,
a first switch connected between a second end of the first capacitor and the sense pin,
a second switch connected between the power supply line and the sense pin,
a third switch connected between the reference pin and the ground line,
a fourth switch connected in parallel to the first capacitor,
a fifth switch connected between a first end of the first capacitor and the reference pin,
a sixth switch connected between the first end of the first capacitor and the ground line, and
a seventh switch connected between the reference pin and the ground line.

5. The electrostatic capacitance detection circuit according to claim 1,
wherein the capacitance detection circuit includes a first capacitor and a second capacitor and is configured to, (i) in a state in which a first end of the second capacitor is connected to the ground pin, apply a voltage to a second end of the second capacitor, (ii) in a state in which the reference pin and the ground pin are electrically connected to each other and the first end of the second capacitor is connected to the ground pin, connect the second end of the second capacitor to the sense pin, and (iii) in a state in which the reference pin and the ground pin are electrically disconnected from each other, connect the first capacitor between the sense pin and the reference pin.

6. The electrostatic capacitance detection circuit according to claim 5,
wherein the capacitance detection circuit is switchable among
a state in which electric charge in the electrostatic capacitance, electric charge in the first capacitor, and electric charge in the second capacitor are initialized to zero,
a state in which the first end on a low potential side of the second capacitor is connected to the ground pin and a voltage is applied to the second end on a high potential side of the second capacitor,
a state in which the reference pin is connected to the ground pin, the first end on the low potential side of the second capacitor is connected to the ground pin, and the second end on the high potential side of the second capacitor is connected to the sense pin,
a state in which the reference pin and the ground pin are electrically disconnected from each other and the first capacitor is connected between the sense pin and the reference pin, and
a state in which a first end on a low potential side of the first capacitor is connected to the ground pin and a voltage of the first capacitor is amplified.

7. The electrostatic capacitance detection circuit according to claim 5,
wherein the capacitance detection circuit includes
a power supply line,
a ground line connected to the ground pin,
a first switch connected between a second end of the first capacitor and the sense pin,
a second switch connected between the second end of the second capacitor and the sense pin,
a third switch connected between the reference pin and the ground line,
a fourth switch connected in parallel to the first capacitor,
a fifth switch connected between a first end of the first capacitor and the reference pin,
a sixth switch connected between the first end of the first capacitor and the ground line,
a seventh switch connected between the reference pin and the ground line,
an eighth switch connected between the power supply line and the second end of the second capacitor, and
a ninth switch connected in parallel to the second capacitor.

8. An electrostatic capacitance detection circuit comprising:
a sense pin;
a ground pin;
a reference pin;
a first capacitor;
a power supply line;
a ground line connected to the ground pin;
a first switch connected between a second end of the first capacitor and the sense pin;
a second switch connected between the power supply line and the sense pin;
a third switch connected between the reference pin and the ground line;
a fourth switch connected in parallel to the first capacitor;
a fifth switch connected between a first end of the first capacitor and the reference pin;
a sixth switch connected between the first end of the first capacitor and the ground line; and
a seventh switch connected between the reference pin and the ground line.

9. An electrostatic capacitance detection circuit comprising:
a sense pin;
a ground pin;
a reference pin;
a first capacitor;
a second capacitor;
a power supply line;
a ground line connected to the ground pin;
a first switch connected between a second end of the first capacitor and the sense pin;
a second switch connected between a second end of the second capacitor and the sense pin;
a third switch connected between the reference pin and the ground line;
a fourth switch connected in parallel to the first capacitor;
a fifth switch connected between a first end of the first capacitor and the reference pin;
a sixth switch connected between the first end of the first capacitor and the ground line;
a seventh switch connected between the reference pin and the ground line;
an eighth switch connected between the power supply line and the second end of the second capacitor; and
a ninth switch connected in parallel to the second capacitor.

10. The electrostatic capacitance detection circuit according to claim 1,
wherein the electrostatic capacitance detection circuit is integrated on a single semiconductor substrate.

11. The electrostatic capacitance detection circuit according to claim 8,
wherein the electrostatic capacitance detection circuit is integrated on a single semiconductor substrate.

12. The electrostatic capacitance detection circuit according to claim 9,
wherein the electrostatic capacitance detection circuit is integrated on a single semiconductor substrate.

13. An electronic device comprising:
a sense electrode; and
the electrostatic capacitance detection circuit according to claim 1.

14. An electronic device comprising:
a sense electrode; and
the electrostatic capacitance detection circuit according to claim 8.

15. An electronic device comprising:
a sense electrode; and
the electrostatic capacitance detection circuit according to claim 9.
